(19) United States
(12) Patent Application Publication
(10) Pub. No.: US 2021/0117770 A1
(43) Pub. Date: Apr. 22, 2021

(54) POWER ELECTRONIC CIRCUIT TROUBLESHOOT METHOD BASED ON BEETLE ANTENNAE OPTIMIZED DEEP BELIEF NETWORK ALGORITHM

(71) Applicant: WUHAN UNIVERSITY, HUBEI (CN)

(72) Inventors: Yigang HE, Hubei (CN); Yaru ZHANG, Hubei (CN); Liulu HE, Hubei (CN)

(73) Assignee: WUHAN UNIVERSITY, HUBEI (CN)

(21) Appl. No.: 15/931,605

(22) Filed: May 14, 2020

(30) Foreign Application Priority Data
Oct. 18, 2019 (CN) 201910993630.6

(51) Int. Cl. G06N 3/08; G06N 3/04; G06K 9/62; G06F 17/18

(52) U.S. Cl. CPC G06N 3/08; G06N 3/04; G06F 17/18; G06K 9/6232; G06K 9/6256

(57) ABSTRACT

A power electronic circuit troubleshoot method based on a beetle antennae optimized deep belief network algorithm including the following steps is provided. Output current signals of DC bus of a three-phase PWM rectifier under different switching device open circuit failure modes are collected as an original data set. Intrinsic mode function components of the output current signals under different switching device open circuit failure modes are extracted using empirical mode decomposition to construct an original failure feature set. Fault feature is selected based on extra-trees to generate final fault dataset. A structure of a deep belief network is optimized using a beetle antennae algorithm. An optimized deep belief network is trained using a training set and an obtained failure recognition result is verified using a testing set.

### CROSS-REFERENCE TO RELATED APPLICATION

This application claims the priority benefit of China application serial no. 201910993630.6, filed on Oct. 18, 2019. The entirety of the above-mentioned patent application is hereby incorporated by reference herein and made a part of this specification.

### BACKGROUND

### Technical Field

The disclosure relates to a power electronic circuit troubleshoot method, and in particular to a power electronic circuit troubleshoot method based on a beetle antennae optimized deep belief network algorithm.

### Description of Related Art

Power electronic technology is a basic subject in emerging integrated application technology. With the advancement and development of technology, the application field of power electronic technology is also expanding. At present, the use of power electronic devices may be observed in fields such as military defense, aerospace, power conversion and transmission, information communication, etc. The power electronic circuit is an important part of the power electronic device, which is mainly composed of two parts, the main circuit and the control circuit. During actual operation, the probability of failure of the main circuit is much higher than that of other components. Failure of any component may cause abnormal operating state of the entire system and device. Therefore, it is very important to monitor and quickly troubleshoot the operating state of the power electronic circuit and device.

At present, power electronic troubleshoot methods are mainly divided into analytical model diagnosis, signal recognition, and knowledge fusion diagnosis. The analytical model troubleshoot method may be further divided into state estimation troubleshoot and parameter estimation troubleshoot, which needs to accurately establish the failure model of the circuit to be diagnosed. The signal recognition is a troubleshoot method based on signal processing with the main characteristic being that there is no need to establish an accurate diagnosis model of the circuit to be diagnosed, so that the signal recognition has strong self-adaptability and selects a suitable circuit output to analyze the containing failure information. Conventional processing methods include Fourier transform, Park transform, and wavelet transform. However, the results of signal processing by the method may not have actual physical significance, valid failure information may be lost during the process, or the failure feature amount selected after transformation cannot effectively distinguish different failure types when there are a lot of failure types. The troubleshoot method based on knowledge fusion is another branch of troubleshoot method developed from the field of power electronic circuit troubleshoot in recent years, such as the artificial neural network. However, there are limitations to such shallow learning network when solving complex high-dimensional data.

### SUMMARY

The disclosure provides a power electronic circuit troubleshoot method based on a beetle antennae optimized deep belief network algorithm, which can perform fast and accurate device-level failure location of power electronic circuit in view of the limitations of current troubleshoot methods.

The power electronic circuit troubleshoot method based on a beetle antennae optimized deep belief network algorithm includes the following steps.

1) Output current signals of DC bus of a three-phase pulse width modulation rectifier under different switching device open circuit failure modes are collected as an original dataset.

2) Intrinsic mode function components of the output current signals under different switching device open circuit failure modes are extracted using empirical mode decomposition and power electronic circuit failure features including time domain, frequency domain, and energy of each order of component is calculated to construct an original failure feature set.

3) Importance of each original failure feature is calculated through extra-trees, a failure feature is selected to remove redundant and interfering features in the original failure feature set, and normalization is performed as a failure feature set, and the failure feature set is divided into a training set and a testing set according to a specific ratio.

4) A deep belief network is adopted as a classifier and a structure of the deep belief network is optimized using a beetle antennae algorithm to obtain a number of hidden layer units, and a number of nodes in an input layer, a hidden layer, and an output layer of a network are set.

5) An optimized deep belief network is trained using the training set and an obtained failure recognition result is verified using the testing set.

In addition, in Step 2), each intrinsic mode function component respectively contains components of different time feature scales of a current signal. A residual component represents an average trend of the current signal and reflects feature information of a power electronic circuit failure.

In addition, the extra-trees in Step 3) specifically calculates a purity of nodes of a decision tree through a Gini index to measure importance of a feature.

In addition, a screened failure feature set includes energy, complexity, mean, root mean square, standard deviation, skewness, kurtosis, waveform index, margin index, pulse index, peak index, kurtosis index, center of gravity frequency, mean square frequency, root mean square frequency, frequency variance, and frequency standard deviation.

In addition, the deep belief network is formed by stacking multiple restricted Boltzmann machines. An independent restricted Boltzmann machine is composed of two layers of neurons, including visible layer neurons and hidden layer neurons. The visible layer neurons are configured to receive input and the hidden layer neurons are configured to extract features.

The disclosure also provides a power electronic circuit troubleshoot system based on a beetle antennae optimized deep belief network algorithm, including: an original data collection module, configured to collect output current signals of DC bus of a three-phase pulse width modulation rectifier under different switching device open circuit failure modes as an original dataset; an original failure feature set construction module, configured to extract intrinsic mode function components of the output current signals under different switching device open circuit failure modes using empirical mode decomposition and calculate power electronic circuit failure features including time domain, frequency domain, and energy of each order of component to construct an original failure feature set; a failure feature set screening module, configured to calculate importance of each original failure feature through extra-trees, select a failure feature to remove redundant and interfering features in the original failure feature set, and perform normalization as a failure feature set, and divide the failure feature set into a training set and a testing set according to a specific ratio; a deep belief network construction module, configured to adopt a deep belief network as a classifier, optimize a structure of the deep belief network using a beetle antennae algorithm, obtain a number of hidden layer units, and set a number of nodes in an input layer, a hidden layer, and an output layer of a network; and a training/testing module, configured to train an optimized deep belief network with the training set and verify an obtained failure recognition result using the testing set.

In addition, a screened failure feature set includes energy, complexity, mean, root mean square, standard deviation, skewness, kurtosis, waveform index, margin index, pulse index, peak index, kurtosis index, center of gravity frequency, mean square frequency, root mean square frequency, frequency variance, and frequency standard deviation.

The disclosure also provides a computer program storage medium with a computer program executable by a processor. The computer program executes the above power electronic circuit troubleshoot method based on a beetle antennae optimized deep network algorithm.

The disclosure selects a failure feature based on a supervised learning extra-trees algorithm, such that the failure feature set is more conducive to subsequent troubleshoot. In addition, the disclosure is different from the traditional method of determining the number of hidden layer units based on habit or limited tests. Also, the disclosure uses the beetle antennae search algorithm to determine an optimal number of hidden layer units, so that a failure classification result is optimal. The disclosure combines feature extraction, optimization, and deep learning classification, which greatly improves feature data amount and classification accuracy of power electronic circuit troubleshoot. In view of hardware failure state of the switching device of the power electronic circuit, fast and accurate device-level failure location can be performed, which has relatively high value in engineering application.

To make the aforementioned and other features of the disclosure more comprehensible, several embodiments accompanied with drawings are described in detail as follows.

### BRIEF DESCRIPTION OF THE DRAWINGS

The disclosure will be further described below with reference to the drawings and embodiments. In the drawings:

FIG. 1 is a flowchart of a power electronic circuit troubleshoot method based on a beetle antennae optimized deep belief network algorithm according to an embodiment of the disclosure.

FIG. 2 is a structural diagram of a deep belief network according to an embodiment of the disclosure.

FIG. 3 is a flowchart of a beetle antennae algorithm according to an embodiment of the disclosure.

FIG. 4 is a simulation model of a three-phase AC/DC pulse width modulation rectifier according to an embodiment of the disclosure.

FIG. 5 is a result diagram of a beetle antennae search algorithm optimized deep belief network structure according to an embodiment of the disclosure.

### DETAILED DESCRIPTION OF DISCLOSED EMBODIMENTS

In order to make the objective, technical solution, and advantages of the disclosure clearer, the disclosure will be further described in detail below in conjunction with the accompanying drawings and embodiments. It should be understood that the specific embodiments described herein are only used to explain the disclosure and are not intended to limit the disclosure.

The disclosure adopts a deep learning algorithm such as a deep belief network (DBN). The performance of a DBN algorithm model is easily affected by the number of hidden layers and the number of units. Therefore, the disclosure adopts a beetle antennae search algorithm (BAS) to optimize the DBN to determine an optimal number of hidden layer units.

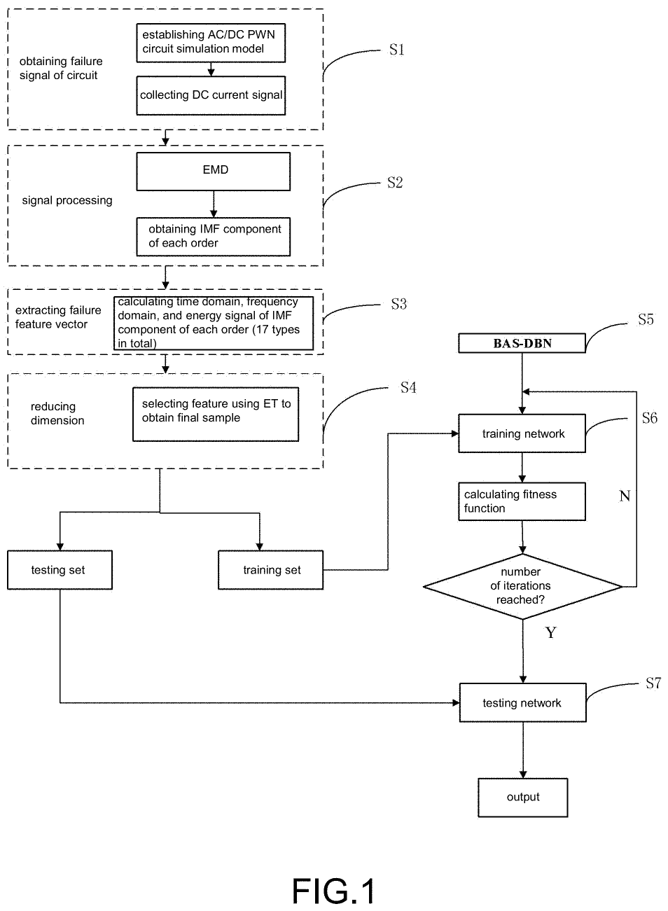

The power electronic circuit troubleshoot method based on a BAS optimized DBN algorithm according to an embodiment of the disclosure is as shown in FIG. 1, the method mainly includes the following steps.

In Step S1, output current signals of DC bus of a three-phase pulse width modulation (PWM) rectifier under different switching device open circuit failure modes are collected as an original dataset.

In Step S2, intrinsic mode function (IMF) components of the output current signals under different switching device open circuit failure modes are extracted using empirical mode decomposition (EMD).

In Step S3, features such as time domain, frequency domain, energy, etc. of each order of IMF component are calculated to construct an original failure feature set.

In Step S4, importance of each feature is calculated based on extra-trees (ET), a feature is selected to remove redundant and interfering features in the original failure feature set, and normalization is performed as a failure feature set, and the failure feature set is divided into a training set and a testing set according to a specific ratio.

In Step S5, a DBN is adopted as a classifier and a structure of the DBN is optimized using a BAS to obtain a number of hidden layer units, and a number of nodes in an input layer, a hidden layer, and an output layer of a network are set.

In Step S6, Steps S1 to S3 are repeated for the three-phase PWM rectifier to obtain the failure feature set of the rectifier circuit and the DBN obtained in Step S5 is trained using the training set.

In Step S7, an obtained failure recognition result is verified using the testing set. A failure recognition result is output through calculating a fitness function (the fitness function is a target function for training the DBN) and setting a number of iterations (such as 50) when the number of iterations is reached.

In the disclosure, the DBN is obtained by training using an offline data sample and the testing set is used to verify the performance of the network. Finally, network training parameters are kept. When a new training data sample is accumulated, the network may be updated again.

In Step S1, a data sample may be obtained by establishing a PWM circuit simulation model to collect open circuit failures of switching devices (a total of 6 switching devices and 6 failure modes) of a rectifier.

In Step S2, each IMF component respectively contains components of different time feature scales of a signal and a residual component represents an average trend of the signal. Therefore, feature information reflecting the power electronic circuit failure may be extracted from the IMF component of the circuit output signal, so the time domain, frequency domain, and energy features of each order of component are selected to be calculated as the original failure features of the power electronic circuit.

The ET in Step S3 uses a Gini index (GI) to calculate a purity of nodes of a decision tree to measure importance of a feature, which is specifically implemented as follows:

Assuming that there are m features X₁, X₂, X₃, . . . Xₘ, variable importance measures (VIM) of each feature may be expressed by a GI score VIMⱼ^{(Gini)}, that is, the average change of node split impurity of the j^{th} feature Xⱼ in all ET decision trees.

The formula for calculating the GI is:

where, K represents that there are K categories and pₘₖ represents the ratio of a category k in a node m. The importance of the feature Xⱼ at the node m, that is, the change of the GI before and after branching of the node m is:

$${VIM}_{jm}^{〈 Gini )} = {GI}_{m} - {GI}_{l} - {GI}_{r}$$

$${GI}_{m} = {\sum }_{k = 1}^{K} {\sum }_{{k}^{′} \neq k} {p}_{m k} {p}_{{mk}^{′}} = 1 - {\sum }_{k = 1}^{K} {p}_{m k}^{2}$$

where, GIₗ and GIᵣ respectively represent the GI of the two new nodes after branching.

If the nodes of the feature Xⱼ appeared in a decision tree i are in a set M, then the importance of Xⱼ at the i^{th} tree is:

$${VIM}_{ij}^{〈 Gini )} = {\sum }_{m ∈ M}^{n} {VIM}_{ij}^{〈 Gini )}$$

Assuming that ET has n trees in total, then

$${VIM}_{j}^{〈 Gini )} = {{\sum }_{i = 1}}^{n} {VIM}_{ij}^{〈 Gini )}$$

Finally, the VIM of the feature through normalization may be obtained as:

$${VIM}_{j} = \frac{{VIM}_{j}}{{\sum }_{i = 1}^{c} {VIM}_{i}}$$

Finally, the obtained VIM are arranged in descending order to determine the ratio to be removed and a new feature set is obtained after the removal.

The construction principle of the DBN in Step S5 is as follows:

1) The DBN is a probability generation model as opposed to the traditional neural network of discriminant models. The DBN is formed by stacking multiple restricted Boltzmann machines (RBM). An independent RBM individual is composed of two layers of neurons, specifically visible layer neurons and hidden layer neurons. The visible layer neurons are configured to receive input and the hidden layer neurons are configured to extract features. The RBM is a model based on energy, so the energy function thereof is:

$$E ( {v}_{v} h \vert θ ) = - {α}^{T} v - {β}^{T} h - {v}^{T} wh = - {\sum }_{i = 1}^{n} {α}_{i} {v}_{i} - {\sum }_{j = 1}^{m} {β}_{j} {h}_{j} - {\sum }_{i = 1}^{n} {\sum }_{j = 1}^{m} {v}_{i} {w}_{ij} {h}_{j}$$

where, v is the input of the visible layer neurons, h is the hidden layer neurons, α and β are respectively the offset of the visible layer neurons and the hidden layer neurons, and w is the connection weight between the visible layer neurons and the hidden layer neurons. The probability distribution for each visible layer neuron and hidden layer neuron may be defined using the following energy function:

$$p ( v , h ) = \frac{1}{Z} exp ( - E ( v , h ) )$$

where, Z is the regularization constant, specifically as follows:

$$Z ( θ ) = {\sum }_{v} {\sum }_{h} exp ( - E ( v , h ) )$$

Then, by summing all possible hidden layer neurons, the probability of a vector v of the visible layer neurons is obtained:

$$p ( v \vert θ ) = {\sum }_{h} p ( v , h ) = \frac{1}{Z} {\sum }_{h} exp ( - E ( v , h ) )$$

Since the neurons in the visible layer and the hidden layer are not interconnected, only the neurons within the layer have symmetrical connecting lines. Therefore, in the case where all visible layer neuron values are given, the values of all hidden layer neurons are not interrelated. Similarly, when all hidden layer neuron values are given, the values of all visible layer neurons are not interrelated. The conditional probability distribution of the visible layer and the hidden layer is as follows:

$$p ( h \vert v ; θ ) = \frac{p ( v , h ; θ )}{p ( v ; θ )} = {\prod }_{j} p ( {h}_{j} \vert v )$$

$$p ( v \vert h ; θ ) = \frac{p ( v , h ; θ )}{p ( h ; θ )} = {\prod }_{j} p ( {v}_{i} \vert h )$$

Considering the binary structure of the RBM, the logistic function is adopted here to normalize the excitation value of each hidden layer neuron. Therefore, the probability of turning on each hidden layer neuron may be obtained when the visible layer is given. Also, when the hidden layer is given, the probability of turning on each visible layer neuron may be obtained:

$$p ( {h}_{j} = 1 \vert v ) = s i g ( {β}_{j} + {\sum }_{i = 1}^{n} {w}_{ij} {v}_{j} )$$

$$p ( {v}_{i} = 1 \vert h ) = sig ( {α}_{i} + {\sum }_{i = 1}^{n} {w}_{ij} {h}_{j} )$$

The training process of the RBM is actually to find a probability distribution most capable of producing a training sample through training adjustment weights and deviations. Therefore, the maximum likelihood function is adopted as follows:

$$\frac{\partial log p ( v )}{\partial θ} = - {\sum }_{h} p ( h \vert v ) \frac{\partial E ( v , h )}{\partial θ} + {\sum }_{v} {\sum }_{h} p ( v \vert h ) \frac{\partial E ( v , h )}{\partial θ} = - {〈 \frac{\partial E ( v , h )}{\partial θ} 〉}_{0} + {〈 \frac{\partial E ( v , h )}{\partial θ} 〉}_{∞}$$

Also, the RBM is trained to update the weights and deviations using the contrastive divergence algorithm shown as follows:

Δw_{g}=ρ( [symbol] vᵢhⱼ [symbol] ₀− [symbol] vᵢhⱼ [symbol] ₖ)

Δαᵢ=ρ( [symbol] vᵢ [symbol] ₀− [symbol] vᵢ [symbol] ₖ)

Δβⱼ=ρ( [symbol] hⱼ [symbol] ₀− [symbol] hⱼ [symbol] ₖ)

where, ρ is the learning rate. The DBN is formed by stacking multiple RBM and the RBM may be trained through the contrastive divergence (CD) algorithm. Each RBM takes the hidden layer output of the RBM of a layer lower as the input, and the output is the input of the RBM of a layer higher. Such layer-by-layer unsupervised training process may be applied to the DBN, which may effectively pre-train the model before finally performing the overall fine-tune.

2) As shown in FIG. 3, the BAS is a new technology based on the foraging principle of the beetle, which is applicable to multi-objective optimization. The biological principle is that when the beetle is foraging, the beetle does not know where is the food and forages based on the smell of the food. The beetle has two long tentacles. If the smell intensity received by the left tentacle is greater than that on the right, then the beetle will fly toward the left, otherwise the beetle will fly toward the right. According to the principle, the beetle will find food. In the disclosure, the BAS is mainly applied to determine the optimal number of hidden layer neurons in the DBN. The fitness function is set as:

$$M S E = \frac{1}{N} {\sum }_{i = 1}^{N} {‖ {y}_{pre} - {y}_{true} ‖}^{2}$$

where, yₚᵣₑ is the predicted value and yₜᵣᵤₑ is the actual value.

According to FIG. 3, the most important weights in the BAS are the left and right positions of the antennae, x_{left} and x_{fight}. In the optimization of the DBN, the corresponding DBN parameters are the number of units in the first hidden layer and the number of units in the second hidden layer. The fitness function is the objective function for training the DBN.

The number of units in the hidden layers of the network may be set according to x_{left} and x_{right}. The network is used to train the training set sample, and then the testing set is used to test the network to obtain a testing set result and calculate the fitness function (that is, the mean square error of the testing set prediction result and actual result).

As shown in FIG. 3, the BAS mainly includes the following steps. First, for optimization of an n-dimensional space, x_{left} is the left antenna coordinate, x_{right} is the right antenna coordinate, x^{t} is the centroid coordinate, and do is the distance between two antennae. Since it is assumed that the direction after the beetle flies to the next step is random, the vector of the right antenna of the beetle pointing to the right antenna is also arbitrary, which may be represented by a random vector b=rands(n, 1) generated. After normalization: b=b/norm(b); x_{left}−x_{right}=d₀*dir may be obtained; obviously, x_{left}=x^{t}d₀*dir/2, x_{right}=x^{t}−d₀*dir/2.

Then, a minimum value is obtained by optimizing an objective function f, the values of the left and right antennae are found: f__{right}=f(x_{right}), f_left=f(x_{left}), and the size of the two are compared. The function is updated as:

x=x−δ*b*sign(f_{left}−f_{right}).

x_{left} and x_{right} are updated, Steps S1 and S2 are looped, and the final x_{left} and x_{right} are obtained after a certain number of iterations (such as 50 times).

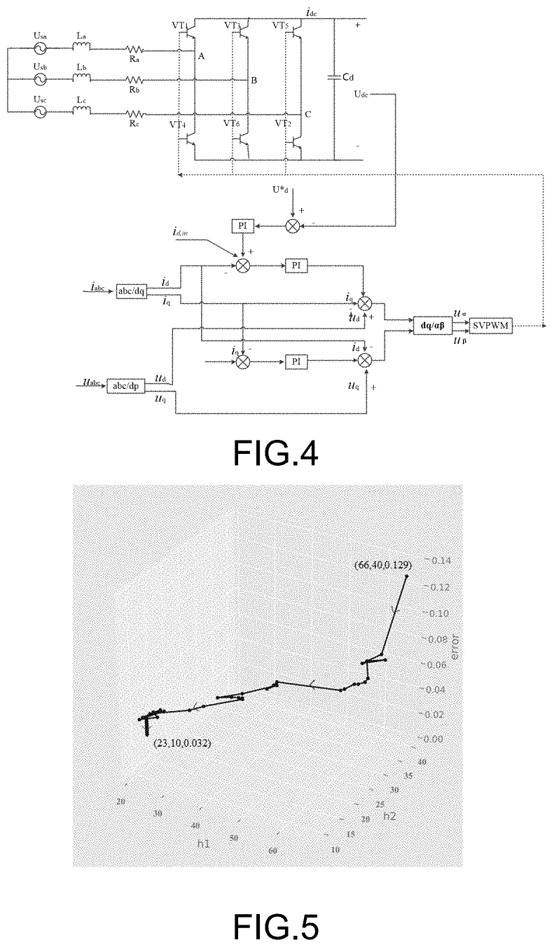

The following uses the circuit shown in FIG. 4 as the circuit to be diagnosed for troubleshoot.

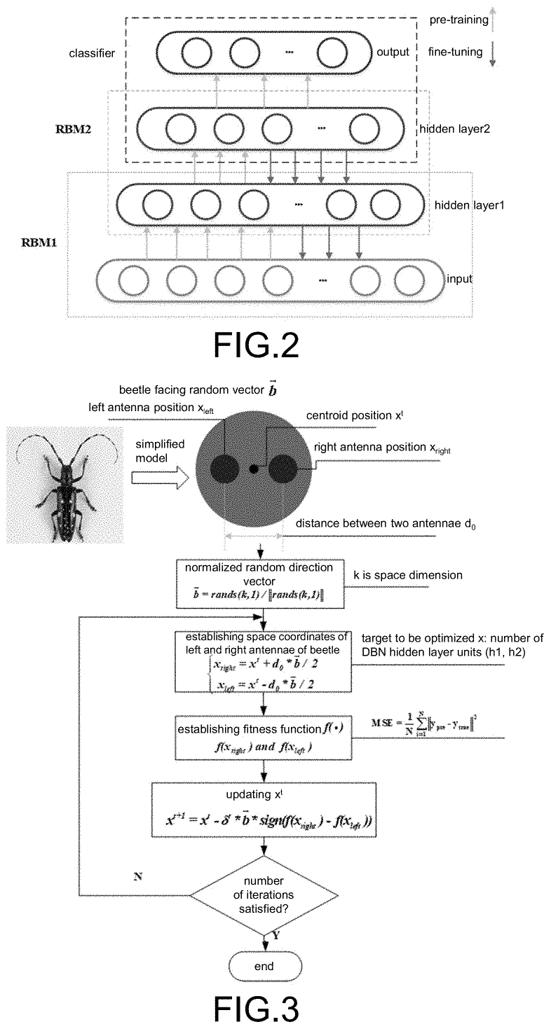

As shown in FIG. 2, a three-phase voltage-type PWM rectifier simulation model is established through MATLAB. The grid phase voltage amplitude is 220\sqrt{2} V, the frequency is 50 Hz, the AC inductance is 1 mH, the parasitic resistance of inductance is 0.5Ω, a DC capacitance C is 4000 uF, the parallel resistance is 10Ω, and the DC voltage is 600V. It is assumed that the switching frequency is 10 kHz, the sampling frequency is 100 kHz, and the inflow of AC current is i_{dc,in}=5 sin 100πt. The controllers thereof all adopt a double closed-loop structure. In a three-phase AC symmetric system, if only the AC fundamental component is considered, the dq component is coupled in the dq coordinate system. Therefore, the current may be decoupled to obtain an independent dq DC component, thereby changing the current tracking system into a constant value adjustment system. If the d-axis coincides with the Us-axis, the d-axis may be expressed as the reference value of the active component and the q-axis represents the reference value of the reactive component, thereby facilitating independent control of active and reactive currents. In the disclosure, the q-axis current is controlled as 0 to ensure that the power factor of the power supply side is 1 and the d-axis current is controlled to keep the DC output voltage constant.

Assuming that there is no load, the output power is 0. If the output DC voltage is a fixed value, the d-axis current at this time should be controlled as 0 and the entirety is in a balanced state, which is not conducive to failure signal extraction. Therefore, in order to collect an effective amount of failure feature extraction on the DC output, AC current of a specific frequency is selected to be injected into the d-axis component of the AC current of the PWM rectifier to produce ripple voltage of the same frequency at the DC output. In the disclosure, current i_{dc,in}=5 sin 100πt is selected to be injected into the d-axis. Due to the existence of the capacitor at the DC output, the voltage drop and harmonic changes caused by certain failures may be compensated, thereby affecting the normal detection of the failure. Therefore, the DC current signal is selected as the failure feature signal here.

The disclosure selects a switching device insulated gate bipolar transistor (IGBT) with failure rate only lower than that of the electrolytic capacitor as the research target. In most cases, overvoltage and overcurrent cause the uncontrollable conduction of the parasitic transistor or diode thereof, resulting in breakdown of the switch and instantaneous failure. The disclosure mainly analyzes the open circuit failure of the switching device IGBT and judges the failure type of the IGBT at different positions. For the unit device failure, 7 failure modes including normal conditions are shown in Table 1. 100 DC current signal samples are extracted from each type of failure mode and each sample contains 10 k points.

TABLE 1
Failure classification and coding

| Failure type | Category | Code |
|---|---|---|
| Normal | 0 | [1, 0, 0, 0, 0, 0, 0] |
| VT₁ open circuit | 1 | [0, 1, 0, 0, 0, 0, 0] |
| VT₂ open circuit | 2 | [0. 0, 1, 0, 0, 0, 0] |
| VT₃ open circuit | 3 | [0, 0, 0, 1, 0, 0, 0] |
| VT₄ open circuit | 4 | [0, 0, 0, 0, 1, 0, 0] |
| VT₅ open circuit | 5 | [0, 0, 0, 0, 0, 1, 0] |
| VT₆ open circuit | 6 | [0, 0, 0, 0, 0, 0, 1] |

EMD is performed on the current signal to obtain the IMF components of the first 7 orders and calculate 17 features thereof (see Table 2) are calculated. A total of 119 types of failure features are obtained. The sample data set at this time is defined as an initial data set A (420*119). Then, the VIM of 119 types of features are calculated using the ET before sorting in descending order. According to the descending order, the rejection ratio is set to 0.6 and a new data set B (420*48) is obtained after the rejection.

TABLE 2
Calculation methods of 17 types of features

| Feature | Formula |
|---|---|
| Energy | ${T}_{1} = {\sum }_{i = 1}^{n} {\vert x ( i ) \vert}^{2}$ |
| Complexity | T₂ = Lempel-Ziv comp |
| Mean | ${T}_{3} = \sqrt{\frac{1}{n} {\sum }_{i = 1}^{n} x ( i )}$ |
| Mean square root | ${T}_{4} = \sqrt{\frac{1}{n} {\sum }_{i = 1}^{n} {\vert x ( i ) \vert}^{2}}$ |
| Standard deviation | ${T}_{5} = \sqrt{\frac{1}{n} {\sum }_{i = 1}^{n} {[ x ( i ) - {T}_{3} ]}^{2}}$ |
| Skewness | ${T}_{6} = \frac{1}{n - 1} {\sum }_{i = 1}^{n} {[ x ( i ) - {T}_{3} ]}^{3}$ |
| Kurtosis | ${T}_{7} = \frac{1}{n - 1} {\sum }_{i = 1}^{n} {[ x ( i ) - {T}_{3} ]}^{4}$ |
| Waveform index | ${T}_{8} = \frac{{T}_{4}}{\vert {T}_{3} \vert}$ |
| Margin index | ${T}_{9} = \frac{max x ( i )}{{[ 1 / n {\sum }_{i = 1}^{n} \sqrt{\vert x ( i ) \vert} ]}^{2}}$ |
| Pulse index | ${T}_{10} = \frac{max x ( i )}{\vert {T}_{3} \vert}$ |
| Peak index | ${T}_{11} = \frac{max x ( l )}{{T}_{4}}$ |
| Kurtosis index | ${T}_{12} = \frac{1 / n {\sum }_{i = 1}^{n} {x ( i )}^{4}}{{T}_{4}^{4}}$ |
| Center of gravity frequency | ${T}_{13} = \frac{\sum f φ ( f )}{\sum φ ( f )}$ |
| Mean square frequency | ${T}_{14} = \frac{\sum {f}^{2} φ ( f )}{\sum φ ( f )}$ |
| Root mean square frequency | T₁₅ = \sqrt{T₁₄} |
| Frequency variance | ${T}_{16} = \frac{\sum {( f - {T}_{13} )}^{2} φ ( f )}{\sum φ ( f )}$ |
| Frequency standard deviation | T₁₇ = \sqrt{T₁₆} |

In Table 2 above, 17 types of features are mainly divided into energy features T₁, complexity features T₂, time-domain features, and frequency-domain features, wherein T₁₃-T₁₇ are frequency-domain features and others are time-domain features.

The disclosure chooses to construct a two-layer DBN structure. The number of DBN input layer units is set as 48 and the number of output layer units is set as 7 according to the dimension of the data set B. The BAS is now used to obtain the number of units of the two DBN hidden layers. The optimized path and the final result are shown in FIG. 5. The final error is obtained as 0.032 and the troubleshoot accuracy rate is 98.42%.

The disclosure also provides a computer program storage medium with a computer program executable by a processor. The computer program executes the power electronic circuit troubleshoot method based on the BAS optimized DBN according to the embodiments above.

It should be understood that those of ordinary skill in the art can make improvements or changes based on the above descriptions, and all such improvements and changes should fall within the protection scope of the appended claims of the disclosure.

What is claimed is:

1. A power electronic circuit troubleshoot method based on a beetle antennae optimized deep belief network algorithm, comprising:
1) collecting output current signals of DC bus of a three-phase pulse width modulation (PWM) rectifier under different switching device open circuit failure modes as an original data set;
2) extracting intrinsic mode function components of the output current signals under different switching device open circuit failure modes using empirical mode decomposition and calculating power electronic circuit failure features comprising time domain, frequency domain, and energy of each order of component to construct an original failure feature set;
3) calculating importance of each original failure feature through extra-trees, selecting a failure feature to remove redundant and interfering features in the original failure feature set, and normalizing as a failure feature set, and dividing the failure feature set into a training set and a testing set according to a specific ratio;
4) adopting a deep belief network as a classifier, optimizing a structure of the deep belief network using a beetle antennae algorithm to obtain a number of hidden layer units, and setting a number of nodes in an input layer, a hidden layer, and an output layer of a network; and
5) training an optimized deep belief network using the training set and verifying an obtained failure recognition result using the testing set.

2. The power electronic circuit troubleshoot method based on a beetle antennae optimized deep belief network algorithm according to claim 1, wherein, in Step 2), each intrinsic mode function component respectively contains components of different time feature scales of a current signal and a residual component represents an average trend of the current signal and reflects feature information of a power electronic circuit failure.

3. The power electronic circuit troubleshoot method based on a beetle antennae optimized deep belief network algorithm according to claim 1, wherein, in Step 3), the extra-trees specifically calculates a purity of nodes of a decision tree through a Gini index to measure importance of a feature.

4. The power electronic circuit troubleshoot method based on a beetle antennae optimized deep belief network algorithm according to claim 1, wherein a screened failure feature set specifically comprises energy, complexity, mean, root mean square, standard deviation, skewness, kurtosis, waveform index, margin index, pulse index, peak index, kurtosis index, center of gravity frequency, mean square frequency, root mean square frequency, frequency variance, and frequency standard deviation.

5. The power electronic circuit troubleshoot method based on a beetle antennae optimized deep belief network algorithm according to claim 1, wherein the deep belief network is formed by stacking a plurality of restricted Boltzmann machines, an independent restricted Boltzmann machine is composed of two layers of neurons, comprising visible layer neurons and hidden layer neurons, the visible layer neurons are configured to receive input, and the hidden layer neurons are configured to extract features.

6. A power electronic circuit troubleshoot system based on a beetle antennae optimized deep belief network algorithm, comprising:
an original data collection module, configured to collect output current signals of DC bus of a three-phase PWM rectifier under different switching device open circuit failure modes as an original data set;
an original failure feature set construction module, configured to extract intrinsic mode function components of the output current signals under different switching device open circuit failure modes using empirical mode decomposition and calculate power electronic circuit failure features comprising time domain, frequency domain, and energy of each order of component to construct an original failure feature set;
a failure feature set screening module, configured to calculate importance of each original failure feature through extra-trees, select a failure feature to remove redundant and interfering features in the original failure feature set, and perform normalization as a failure feature set, and divide the failure feature set into a training set and a testing set according to a specific ratio;
a deep belief network construction module, configured to adopt a deep belief network as a classifier, optimize a structure of the deep belief network using a beetle antennae algorithm to obtain a number of hidden layer units, and set a number of nodes in an input layer, a hidden layer, and an output layer of a network; and
a training/testing module, configured to train an optimized deep belief network using the training set and verify an obtained failure recognition result using the testing set.

7. The power electronic circuit troubleshoot system based on a beetle antennae optimized deep belief network algorithm according to claim 6, wherein a screened failure feature set specifically comprises energy, complexity, mean, root mean square, standard deviation, skewness, kurtosis, waveform index, margin index, pulse index, peak index, kurtosis index, center of gravity frequency, mean square frequency, root mean square frequency, frequency variance, and frequency standard deviation.

8. A computer program storage medium with a computer program executable by a processor, wherein the computer program executes the power electronic circuit troubleshoot method based on a beetle antennae optimized deep belief network algorithm according to claim 1.

9. A computer program storage medium with a computer program executable by a processor, wherein the computer program executes the power electronic circuit troubleshoot method based on a beetle antennae optimized deep belief network algorithm according to claim 2.

10. A computer program storage medium with a computer program executable by a processor, wherein the computer program executes the power electronic circuit troubleshoot method based on a beetle antennae optimized deep belief network algorithm according to claim 3.

11. A computer program storage medium with a computer program executable by a processor, wherein the computer program executes the power electronic circuit troubleshoot method based on a beetle antennae optimized deep belief network algorithm according to claim 4.

12. A computer program storage medium with a computer program executable by a processor, wherein the computer program executes the power electronic circuit troubleshoot method based on a beetle antennae optimized deep belief network algorithm according to claim 5.
